(19) United States
(12) Patent Application Publication
(10) Pub. No.: US 2004/0132289 A1
(43) Pub. Date: Jul. 8, 2004

(54) Transparent ceramics and method for producing the same

(76) Inventors: Tatsuhiro Sato, Fukushima (JP); Nobumasa Yoshida, Fukushima (JP); Akira Fujinoki, Fukushima (JP)

Correspondence Address: TIAJOLOFF & KELLY, CHRYSLER BUILDING, 37TH FLOOR, 405 LEXINGTON AVENUE, NEW YORK, NY, 10174, US

(21) Appl. No.: 10/474,150

(22) PCT Filed: Jan. 14, 2002
(86) PCT No.: PCT/EP02/00302

(30) Foreign Application Priority Data
Jan. 19, 2001 (JP) 200111924

(51) Int. Cl. H01L 21/302; H01L 21/461

(52) U.S. Cl. 438/689

(57) ABSTRACT

An object of the present invention is to provide a transparent ceramics which exhibits favorable slope efficiency well comparable to that of a single crystal when employed in solid lasers, yet having a uniform quality and internally free from pores, foreign matters, or granular structures. Another object of the present invention is to provide a production method therefor. The above problems have been overcome by a transparent ceramices the physical properties thereof is improved by doping a metallic element, provided that the concentration of the doped metallic elements is in a range of from 0.1 to 20% by weight, that a body of said ceramics has pores and foreign matters accounting for less than 100 mm² per 100 cm³ as expressed by their projected area, and that is has an internal transmittance for visible radiations of 50%/cm or higher.

### TECHNICAL FIELD OF THE INVENTION

The present invention relates to a transparent ceramics suitably used as a material for a solid laser utilized in medicals, marking of semiconductors, metal processing, etc., and to a method for producing the same.

### RELATED TECHNOLOGY

Solid lasers are used in medicals, marking of semiconductors, metal processing, and furthermore, as light sources for nuclear fusion and the like; thus, the field of their application and the field are steadily expanding. Solid lasers can be roughly classified into crystalline and amorphous (glass) lasers, however, the former, which are superior in thermal and mechanical characteristics, are only used in the industry.

Among the solid lasers, YAG (Y₃Al₅O₁₂) is superior from the viewpoint of overall characteristics, and so far this field depends on the present technique of growing single crystals, the possibility of discovering a new material superior than YAG is extremely low. Concerning industrial lasers, only YAG single crystals containing added therein Nd³⁺, which is the active ion relevant to the emission, account for most of the applications. Although Nd:YAG single crystals require one to three months for their growth, the portion usable as the laser medium is limited to a part of the ingot, and this has been found as a factor hindering the prevailed use of lasers due to the incompatibility in economically establishing high performance.

In the Nd:YAG single crystals, a core is detected at the central portion of the single crystal ingot, and facets (which are optically heterogeneous) extending from the center to the peripheral portions are found to be present. Since usable portions are only limited to the outer peripheral portions, the production yield is found to be extremely low. Furthermore, concerning the segregation coefficient of 0.2 for Nd in YAG, which signifies that Nd accounts for only about 1% by weight in the solid solution, there are disadvantages of low optical absorption coefficient and of causing concentration extinction (an extreme drop in fluorescence due to the interaction among the light-emitting ions). Hence, although Nd:YAG is inferior to none in the overall characteristics as a laser material, there still remain technical and economical problems above to be solved.

In the fabrication of an optical grade ceramics, there should be employed a powder starting material which easily sinters almost completely in the low temperature region to yield a dense body. In order to fabricate a transparent ceramics of a general use grade, there is employed a simple method comprising using a high quality powder starting material alone, in which sintering is applied thereto after adding a sintering aid for accelerating the densification. The transparent ceramics used to the present require that they simply have a function of transmitting light, however, in case of lasers, an extremely high quality is required to the material because optical amplification takes place within the medium. For instance, a slight distribution in refractive indices, a precipitation of a grain boundary phase, or residual pores inside the ceramics may lead to fatal effects such as a considerably high drop in laser emitting efficiency or an impaired beam quality. Hence, there is required to obtain ceramics having an ideal texture (i.e., a structure free from micro and macro defects).

In general, solid raw material is used in the production of ceramics. However, a solid raw material has poor pressure transmission, and tends to form fluctuation in quality due to the difference in pressure distribution between the outer peripheral portion and the inner portion within the molding. In order to compensate for such a heterogeneity in the packing of powder, forced removal of defects has been studied by using, for instance, an intermittent application of CIP (Cold Isostatic Pressing) or high-pressure sintering process such as HP (Hot Pressing), HIP (Hot Isostatic Pressing), etc., still, however, there generated a fluctuation in quality generated due to the difference in pressure distribution between the outer peripheral portion and the inner portion within the molding, or pores, foreign matters, and granular structures, tended to form inside the molding.

### PROBLEMS THE INVENTION IS TO SOLVE

The present invention has been made in the light of the aforementioned problems of the prior art technology, and an object of the present invention is to provide a transparent ceramics free from fluctuation in quality and containing no pores, foreign matters, and granular structures inside the structure, and thereby yields a favorable slope efficiency well comparable to that of a single crystal when used in a solid laser. Another object of the present invention is to provide a method for producing the same.

### MEANS FOR SOLVING THE PROBLEMS

In order to solve the problems above, the present invention provides a transparent ceramics the physical properties thereof is improved by doping a metallic element, provided that the concentration of the doped metallic elements is in a range of from 0.1 to 20% by weight, that said ceramics has pores and foreign matters accounting for less than 100 mm² per 100 cm³ as expressed by their projected area, and that it has an internal transmittance for visible radiations of 50%/cm or higher.

Preferably, the OH concentration of the transparent ceramics body above is 100 ppm or lower, and the ceramics body contains no granular structure. As the doped metallic element is preferably Nd, and said ceramics is preferably YAG. The transparent ceramics is favorably used for a solid laser.

The method for producing a transparent ceramics according to the present invention is characterized by that the process comprises producing a transparent ceramics by preparing a mixed powder by mixing a powder of a compound of a metallic element with a ceramic powder, and by then heating and fusing the mixed powder in accordance with Verneuil process, wherein the compound of the metallic element is an oxide of the metallic element, and the powder of said oxide of the metallic element and the ceramics powder both have a granularity in a range of from 0.01 to 50 μm.

In the Verneuil process above, electric fusion is favorably used for the heating method, and arc flame method and the like is known as the electric fusion method. Most preferably, the doped metallic element is Nd, and said ceramic powder consists of YAG particles.

The metallic element above must be uniformly doped into the ceramic body. The metallic elements to be doped are lanthanides represented by Nd and Sm, and the transparent body thus formed is used for a solid laser and the like.

As a means of doping the metallic element above, known is a method comprising melting and depositing a mixture of a ceramic powder and a powder of the compound of the metallic element in accordance with Verneuil method. In accordance with this method, heat supply is efficiently provided to each of the particles as to effectively allow the metallic elements to uniformly disperse on the surface of the ceramic powder. In this manner, light scattering is suppressed to provide a transparent glass body.

In order to obtain a glass body free from granular structures, the finer the ceramic powder and the powder of the metallic element oxides are, the more effectively can the metallic elements be uniformly dispersed. The granularity for both of the powders is preferably in a range of from 0.01 to 50 μm. If a powder less than 0.01 μm in granularity is used, there occurs problems in production; if a powder exceeding 50 μm in granularity is used, the granular structure tends to appear extremely strong.

Since the OH concentration in the produced ceramic body is the source of absorbing a laser radiation, the concentration is preferably lowered as possible, and it can be effectively reduced by heating in electric melting.

The content of the pores and foreign matters in a transparent body obtained by the method described above was found to be less than 100 mm² per 100 cm³ as expressed by the projected area, and the internal transmittance of a visible radiation was found to be 50%/cm or higher. Sufficiently high emission efficiency could not be obtained if the concentration of the doped metallic element was less than 0.1 wt. %, and the generation of pores and foreign matters could not be suppressed under any conditions in case the concentration of the doped metallic element exceeded 20 wt. %.

### EXAMPLES

The present invention is described in detail by way of examples below, but it should be understood that the present invention is not limited thereby.

### Example 1

A 28,500-g portion of YAG particles from 0.1 to 50 μm in particle diameter was mixed with 1,500 g of Nd₂O₃ powder consisting of particles from 0.1 to 30 μm in particle diameter, and the resulting mixture was fused and dropped at a rate of 50 g/min onto a target ingot rotated at 1 rpm in an arc plasma to obtain an ingot 200 mmφ in diameter and 150 mm in length.

The OH concentration of the ceramic body thus obtained was found to be 50 ppm. The content of the pores and foreign matters in a transparent body obtained by the method described above was found to be less than 20 mm² per 100 cm³ as expressed by the projected area, and the internal transmittance of a visible radiation was found to be 80%/cm. No granular structure was observed.

On measuring the Nd concentration by means of X-ray fluorescent analysis, a value of 3.0 wt. % was obtained. On exciting the sample thus obtained with a semiconductor laser emitting a radiation of 808 nm in wavelength, a slope efficiency (i.e., a conversion efficiency after emitting a laser radiation) of 25%, a value well comparable to that of a single crystal, was obtained.

### Comparative Example 1

A 28,500-9 portion of YAG particles from 0.1 to 50 μm in particle diameter was mixed with 1,500 g of Nd₂O₃ powder consisting of particles from 0.1 to 30 μm in particle diameter, and the resulting mixture was heated and fused at 1800° C. to obtain an ingot 200 mmφ in diameter and 150 mm in length. The OH concentration was found to be 50 ppm. On measuring the Nd concentration by means of X-ray fluorescent analysis, a value of 3.0 wt. % was obtained.

However, numerous pores and foreign matters were found to generate inside the ingot at a concentration of 200 mm² per 100 cm³ as expressed by the projected area, and the internal transmittance of a visible radiation was found to be 20%/cm. On exciting the sample thus obtained with a semiconductor laser emitting a radiation of 808 nm in wavelength, a slope efficiency (i.e., a conversion efficiency after emitting a laser radiation) of 1% was obtained.

### Comparative Example 2

A 20,000-g portion of YAG particles from 0.1 to 50 μm in particle diameter was mixed with 10,000 g of Nd₂O₃ powder consisting of particles from 0.1 to 30 μm in particle diameter, and the resulting mixture was fused and dropped at a rate of 50 g/min onto a target ingot rotated at 1 rpm in arc flame to obtain an ingot 200 mm in diameter and 150 mm in length.

Numerous pores and foreign matters were found to generate inside the ingot at a concentration of 200 mm² per 100 cm³ as expressed by the projected area, and the internal transmittance of a visible radiation was found to be 20%/cm. The OH concentration of obtained ceramics body was found to be 50 ppm. On measuring the Nd concentration by means of X-ray fluorescent analysis, a value of 21 wt. % was obtained. On exciting the sample thus obtained with a semiconductor laser emitting a radiation of 808 nm in wavelength, a slope efficiency (i.e., a conversion efficiency after emitting a laser radiation) of 1% was obtained.

Effect of the Invention

As described above, the transparent ceramics according to the present invention was found to have no fluctuation in quality and free from internal pores and foreign matters, and that it is effective in that it exhibits favorable slope efficiency well comparable to that of a single crystal when used as a solid laser. In accordance with the production method of the present invention, it advantageously enables efficient production of a transparent ceramics according to the present invention.

1. A transparent ceramics the physical properties thereof is improved by doping a metallic element, provided that the concentration of the doped metallic elements is in a range of from 0.1 to 20% by weight, that a body of said ceramics has pores and foreign matters accounting for less than 100 mm² per 100 cm³ as expressed by their projected area, and that it has an internal transmittance for visible radiations of 50%/cm or higher.

2. A transparent ceramics as claimed in claim 1, wherein said ceramics body has an OH concentration of 100 ppm or lower.

3. A transparent ceramics as claimed in claim 1 or 2, wherein said ceramics body is free from a granular structure.

4. A transparent ceramics as claimed in one of claims 1 to 3, wherein the doped metallic element is Nd, and said ceramics is YAG.

5. A transparent ceramics as claimed in one of claims 1 to 4, which is used as a solid laser.

6. A method for producing a transparent ceramics, which comprises producing a transparent ceramics by preparing a mixed powder by mixing a powder of a compound of a metallic element with a ceramic powder, and by then heating and fusing the mixed powder in accordance with Verneuil process, wherein the compound of the metallic element is an oxide of the metallic element, and the powder of said oxide of the metallic element and the ceramics powder both have a granularity in a range of from 0.01 to 50 μm.

7. A method for producing a transparent ceramics as claimed in claim 6, wherein the heating method in said Verneuil process is electric fusion.

8. A method for producing a transparent ceramics as claimed in claim 6 or 7, wherein the metallic element is Nd and the ceramics powder consists of YAG particles.
